(19) United States
(12) Patent Application Publication
(10) Pub. No.: US 2013/0056713 A1
(43) Pub. Date: Mar. 7, 2013

(54) ORGANIC LIGHT EMITTING DIODE AND METHOD OF FABRICATING THE SAME

(71) Applicants: Jae Bon KOO, Daejeon (KR); In-Kyu YOU, Daejeon (KR); Yong Suk YANG, Daejeon (KR); Tae-Youb KIM, Seoul (KR); Minseok KIM, Cheongju-si (KR)

(72) Inventors: Jae Bon KOO, Daejeon (KR); In-Kyu YOU, Daejeon (KR); Yong Suk YANG, Daejeon (KR); Tae-Youb KIM, Seoul (KR); Minseok KIM, Cheongju-si (KR)

(73) Assignee: ELECTRONICS AND TELECOMMUNICATIONS RESEARCH INSTITUTE, Daejeon (KR)

(21) Appl. No.: 13/542,156

(22) Filed: Jul. 5, 2012

(30) Foreign Application Priority Data
Sep. 2, 2011 (KR) 10-2011-0089028

(51) Int. Cl. H01L 51/52; H01L 51/56

(52) U.S. Cl. 257/40; 438/46; 257/E51.018; 257/E51.001

(57) ABSTRACT

The inventive concept provides organic light emitting diodes and methods of fabricating the same. The method may include forming an insulating layer on a substrate, coating a metal ink on the insulating layer, thermally treating the substrate to permeate the metal ink into the insulating layer, thereby forming an assistant electrode layer the insulating layer and the metal ink embedded in the insulating layer, and sequentially forming a first electrode, an organic light emitting layer, a second electrode on the assistant electrode layer.

### CROSS-REFERENCE TO RELATED APPLICATIONS

This U.S. non-provisional patent application claims priority under 35 U.S.C. §119 to Korean Patent Application No. 10-2011-0089028, filed on Sep. 2, 2011, the entirety of which is incorporated by reference herein.

### BACKGROUND

The inventive concept relates to organic light emitting diodes and, more particularly, to organic light emitting diodes and methods of fabricating the same.

An organic light emitting diode (OLED) may be a self-emitting device which electrically excites an organic light emitting material to emit light. The organic light emitting diode may include a substrate, a first electrode, a second electrode, and an organic light emitting layer formed between the first and second electrodes. Holes and electrons supplied from the first and second electrodes may be combined with each other in the organic light emitting layer to generate light outputted to the outside of the organic light emitting layer. The organic light emitting diode may output various colors of light according to kinds of materials constituting the organic light emitting layer. Additionally, the organic light emitting diode may have excellent display characteristics such as wide view angle, fast response speed, thin thickness, low fabricating cost, and high contrast. Thus, the organic light emitting diode are attractive in next generation-flat panel display devices and next generation-illumination.

Meanwhile, in the organic light emitting diode used as the illumination, indium tin oxide (ITO) used as an anode may have a high electrical resistivity of about 10⁻⁴ Ωcm. Thus, voltage drop may increase as distance from an electrode group part increases. Accordingly, when wide light source is fabricated, non-uniformity of brightness may be caused by the voltage drop.

### SUMMARY

Embodiments of the inventive concept may provide organic light emitting diodes with high reliability and methods of fabricating the same.

In one aspect, a method of fabricating a organic light emitting diode may include: forming an insulating layer on a substrate; coating a metal ink on the insulating layer; thermally treating the substrate to permeate the metal ink into the insulating layer, thereby forming an assistant electrode layer including the insulating layer and the metal ink embedded in the insulating layer, and sequentially forming a first electrode, an organic light emitting layer, a second electrode on the assistant electrode layer.

In some embodiments, the insulating layer may include at least one of polymethylmethacrylate (PMMA), polyimide (PI), polystyrene (PS), polyvinylphenol (PVP), acryl-based polymer, and epoxy-based polymer. Coating the metal ink may include: coating the metal ink in a mesh grid-shape on the insulating layer in a plan view. The metal ink may include at least one of silver (Ag), gold (Au), copper (Cu) and any alloy thereof. A width of the embedded metal ink may have a range of about 10 μm to about 200 μm.

In another aspect, a method of fabricating an organic light emitting diode may include: forming an insulating layer on a substrate; forming a trench in the insulating layer; filling the trench with a metal ink to form an assistant electrode layer including the insulating layer and the metal ink in the insulating layer; and sequentially forming a first electrode, an organic light emitting layer, a second electrode on the assistant electrode layer.

In some embodiments, the insulating layer may include at least one of polymethylmethacrylate (PMMA), polyimide (PI), polystyrene (PS), polyvinylphenol (PVP), acryl-based polymer, and epoxy-based polymer. Forming the trench may include: forming the trench in the insulating layer by using an imprint roll. The trench may be formed in a mesh grid-shape in the insulating layer in a plan view.

In other embodiments, forming the assistant electrode layer may include: filling the trench with the metal ink by a doctor blading method. The metal ink may include at least one of silver (Ag), gold (Au), copper (Cu) and any alloy thereof. A width of the metal ink in the trench may have a range of about 10 μm to about 200 μm.

In still another aspect, an organic light emitting diode may include: a substrate; a first electrode, an organic light emitting layer, and a second electrode sequentially stacked on the substrate; and an assistant electrode layer disposed between the substrate and the first electrode. The assistant electrode layer may include an insulating layer and an assistant electrode embedded in the insulating layer.

In some embodiments, the assistant electrode layer may include the assistant electrode formed in a mesh grid-shape in a plan view. The insulating layer may include at least one of polymethylmethacrylate (PMMA), polyimide (PI), polystyrene (PS), polyvinylphenol (PVP), acryl-based polymer, and epoxy-based polymer. The assistant electrode may include at least one of silver (Ag), gold (Au), copper (Cu) and any alloy thereof. A width of the assistant electrode has a range of about 10 μm to about 200 μm.

### BRIEF DESCRIPTION OF THE DRAWINGS

The inventive concept will become more apparent in view of the attached drawings and accompanying detailed description.

FIGS. 1 and 2 are cross-sectional views to explain organic light emitting diodes including an assistant electrode;

FIGS. 3 to 5 and 7 are cross-sectional views illustrating a method of fabricating an organic light emitting diode according to some embodiments of the inventive concept;

FIG. 6 is a plan view of a structure of FIG. 5 to explain a method of fabricating an organic light emitting diode according to some embodiments of the inventive concept;

FIGS. 8, 10 and 11 are cross-sectional views illustrating a method of fabricating an organic light emitting diode according to other embodiments of the inventive concept; and

FIG. 9 is a perspective view of a structure of FIG. 8 to explain a method of fabricating an organic light emitting diode according to other embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

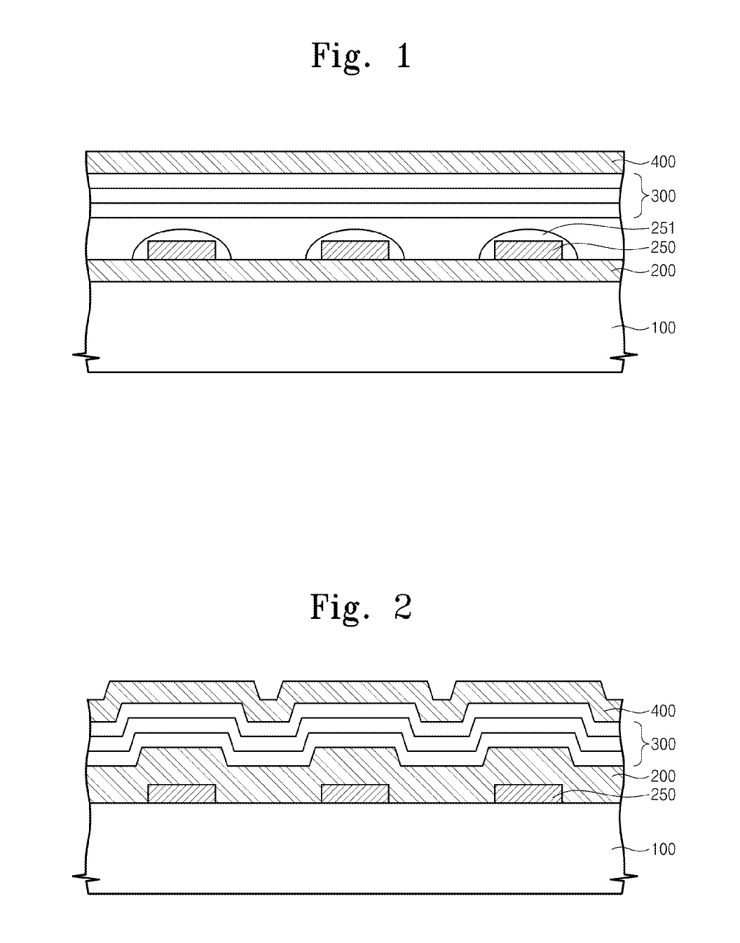

FIGS. 1 and 2 are cross-sectional views to explain organic light emitting diodes including an assistant electrode.

Referring to FIG. 1, an anode 200 may be formed on a substrate 100 and then an assistant electrode 250, an organic light emitting layer 300, and a cathode 400 may be sequentially formed on the anode 200. Here, if the assistant electrode 250 is in contact with the organic light emitting layer 300, a current may be concentrated to the assistant electrode 250, and a local short may occur in the organic light emitting layer 300 due to a height difference caused by the assistant electrode 250. Thus, a bank layer 251 of an organic material may be formed to surround the assistant electrode 250, such that a gradient by the height difference of the assistant electrode 250 may become gentle. Additionally, the assistant electrode 250 may be spaced apart from the organic light emitting layer 300. As a result, it is possible to prevent or minimize the local short of the organic light emitting layer 300. However, the above manufacturing processes may be complicated.

Referring to FIG. 2, the assistant electrode 250 may be first formed on the substrate 100 and then the anode 200, the organic light emitting layer 300, and the cathode 400 may be sequentially formed on the assistant electrode 250. Since the assistant electrode 250 is formed under the anode 200, the formation of the bank layer 251 of FIG. 1 may be omitted. However, the anode 200, the organic light emitting layer 300, and the cathode 400 on the assistant electrode 250 may be formed not to be parallel to the substrate 100 but to be winding due to the height difference and surface roughness of the assistant electrode 250. Thus, a conventional organic light emitting diode illustrated in FIG. 2 may have a low reliability and a short life.

The inventive concept is designed for resolving the above problems of organic light emitting diodes. According to embodiments of the inventive concept, an assistant electrode may be formed under the anode 200 for omitting the formation of the bank layer 251 surrounding the assistant electrode 250, and the assistant electrode may be formed in an embedded type within an insulating layer for preventing the height difference caused by the assistant electrode 250. Thus, it is possible to simplify the manufacturing processes and to provide a high reliability organic light emitting diode including a flat organic light emitting layer without winding. Thus, the above problems may be resolved.

Hereinafter, a method of manufacturing an organic light emitting diode according to some embodiments of the inventive concept will be described in more detail.

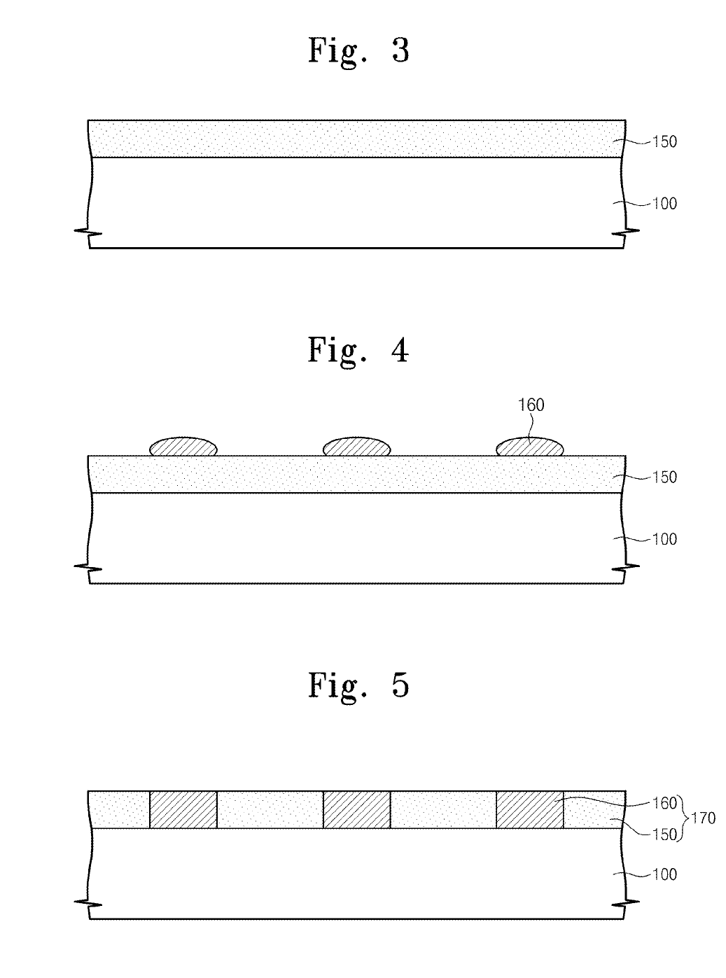

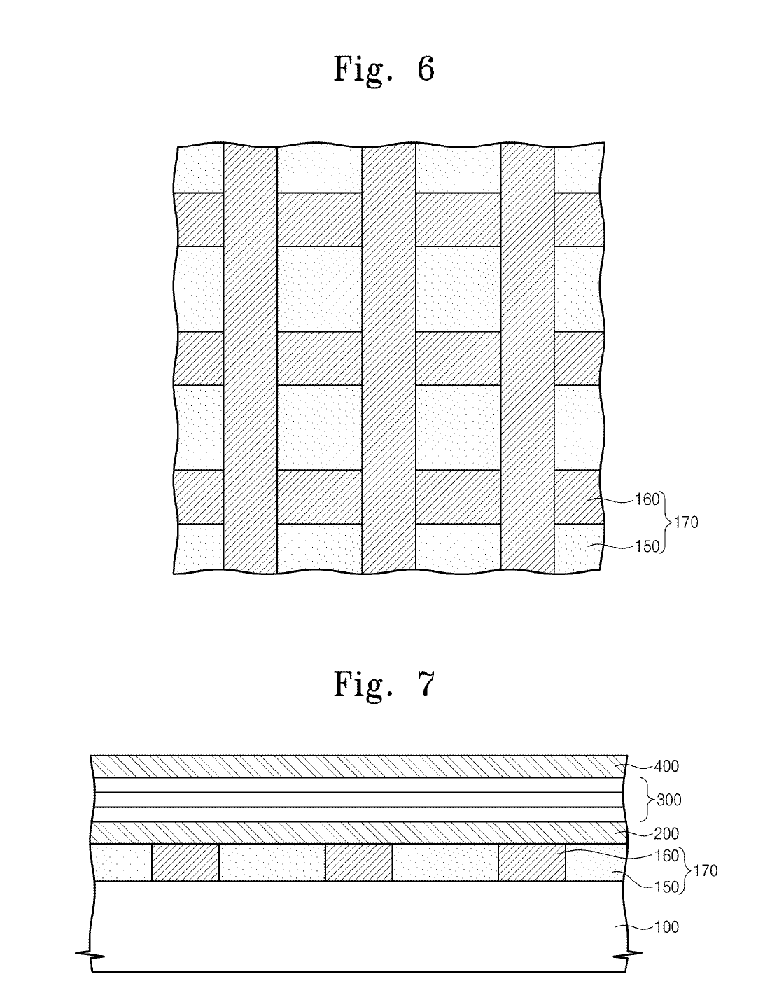

FIGS. 3 to 5 and 7 are cross-sectional views illustrating a method of fabricating an organic light emitting diode according to some embodiments of the inventive concept, and FIG. 6 is a plan view of a structure of FIG. 5.

Referring to FIG. 3, an insulating layer 150 may be formed on a substrate 100. The substrate 100 may include at least one of transparent materials. For example, the substrate 100 may include at least one of glass, quartz, and transparent plastics. The insulating layer 150 may include an organic material. For example, the insulating layer 150 may include at least one of polymethylmethacrylate (PMMA), polyimide (PI), polystyrene (PS), polyvinylphenol (PVP), acryl-based polymer, and epoxy-based polymer. The insulating layer 150 may be formed on the substrate 100 by a spin coating method, a slot die coating method, or a slit die coating method.

Referring to FIG. 4, a metal ink 160 for forming an assistant electrode layer may be coated on the insulating layer 150. The metal ink 160 may be partially formed on the insulating layer 150.

In some embodiments, as illustrated in FIG. 5, an assistant electrode layer 170 may be formed on the substrate 100. For example, the assistant electrode layer 170 may be formed by a printing method. In other words, a thermal process may be performed on the substrate 100 including the insulating layer 150 on which the metal ink 160 is formed. The metal ink 160 may permeate into the insulating layer 150 by the thermal process. Thus, the assistant electrode layer 170 may be formed to include the insulating layer 150 and the metal ink 160 embedded within the insulating layer 150. The embedded metal ink 160 may correspond to an assistant electrode. A width of the embedded metal ink 160 may have a range of about 10 μm to about 200 μm.

Referring to FIG. 6, the metal ink 160 may be formed to have a mesh grid-shape in the insulating layer 150 in a plan view. The metal ink 160 may include at least one of silver (Ag), gold (Au), copper (Cu) and any alloy thereof.

Referring to FIG. 7, a first electrode 200, an organic light emitting layer 300, and a second electrode 400 may be sequentially formed on the assistant electrode layer 170.

The first electrode 200 may be formed of a conductive material having transparency. For example, the first electrode 200 may be formed of at least one of transparent-conductive oxides (TCO). In some embodiments, the first electrode 200 may be formed of indium tin oxide (ITO) and/or indium zinc oxide (IZO).

The organic light emitting layer 300 may include at least one of organic light emitting materials. For example, the organic light emitting layer 300 may include at least one of polyfluorene derivatives, (poly)paraphenylenevinylene derivatives, polyphenylene derivatives, polyvinylcarbazole derivatives, polythiophene derivatives, anthracene derivatives, butadiene derivatives, tetracene derivatives, distyrylarylene derivatives, benzazole derivatives, and carbazole.

In other embodiments, the organic light emitting layer 300 may be formed of at least one of organic light emitting materials doped with impurities. For example, the impurities of the organic light emitting layer 300 may include at least one of xanthene, perylene, cumarine, rhodamine, rubrene, dicyanomethylenepyran, thiopyran, (thia)pyrilium, periflanthene derivatives, indenoperylene derivatives, carbostyryl, nile red, and quinacridone. And the organic light emitting material of the organic light emitting layer 300 may include at least one of polyfluorene derivatives, (poly)paraphenylenevinylene derivatives, polyphenylene derivatives, polyvinylcarbazole derivatives, polythiophene derivatives, anthracene derivatives, butadiene derivatives, tetracene derivatives, distyrylarylene derivatives, benzazole derivatives, and carbazole.

The organic light emitting layer 300 may have a single-layered structure or a multi-layered structure including an assistant layer. In some embodiments, the organic light emitting layer 300 may further include the assistant layer for increasing luminous efficiency of the organic light emitting layer 300. The assistant layer may include at least one of a hole injecting layer, a hole transfer layer, an electron transfer layer, and an electron injecting layer. The organic light emitting layer 300 may generate light by recombination of holes and/or electrons supplied from the first electrode 200 and/or the second electrode 400.

The second electrode 400 may include a conductive material. The second electrode 400 may include a metal and/or a transparent-conductive material. For example, the metal may include at least one of aluminum (Al), silver (Ag), magnesium (Mg), molybdenum (Mo), and any alloy thereof. A thin layer of the metal may be used as the transparent-conductive material of the second electrode 400. A wavelength of a transmitted light may be changed according to a thickness of the thin layer of the metal.

The second electrode 400 may be applied with a voltage from an external system, so that the second electrode 400 may apply electrons into the organic light emitting layer 300. The light generated from the organic light emitting layer 300 may pass through the second electrode 400 or be reflected by the second electrode 400 toward the first electrode 200.

A protection layer (not shown) may further be disposed on the second electrode 400. The protection layer may be formed of a material preventing or minimizing penetration of air and moisture. Additionally, the protection layer may be formed of a transparent material. The protection layer may cover the organic light emitting diode.

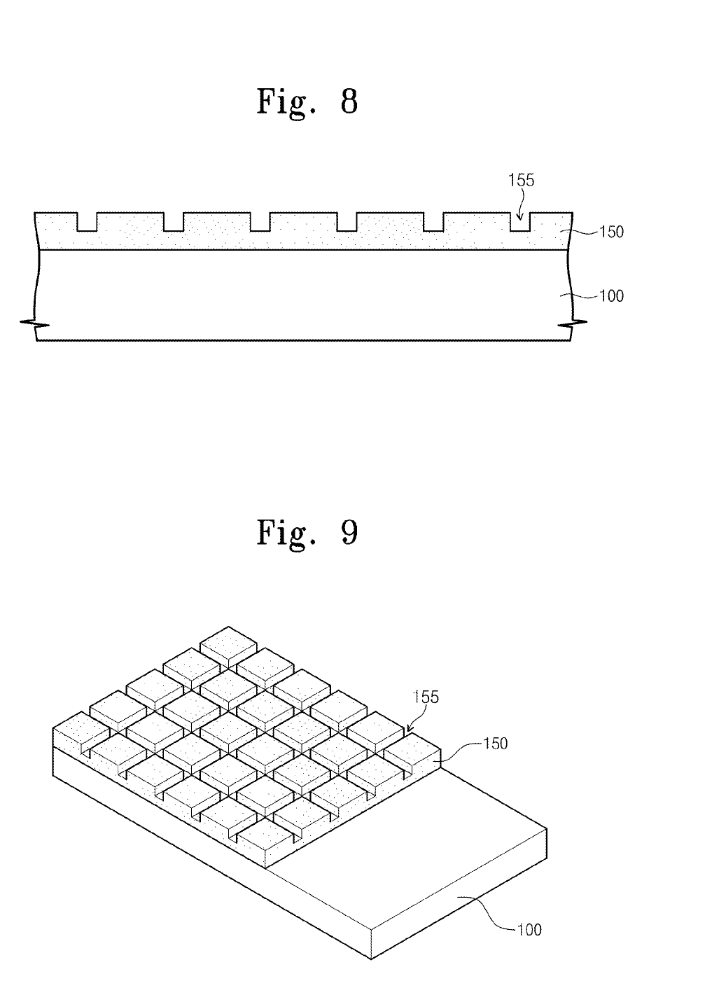

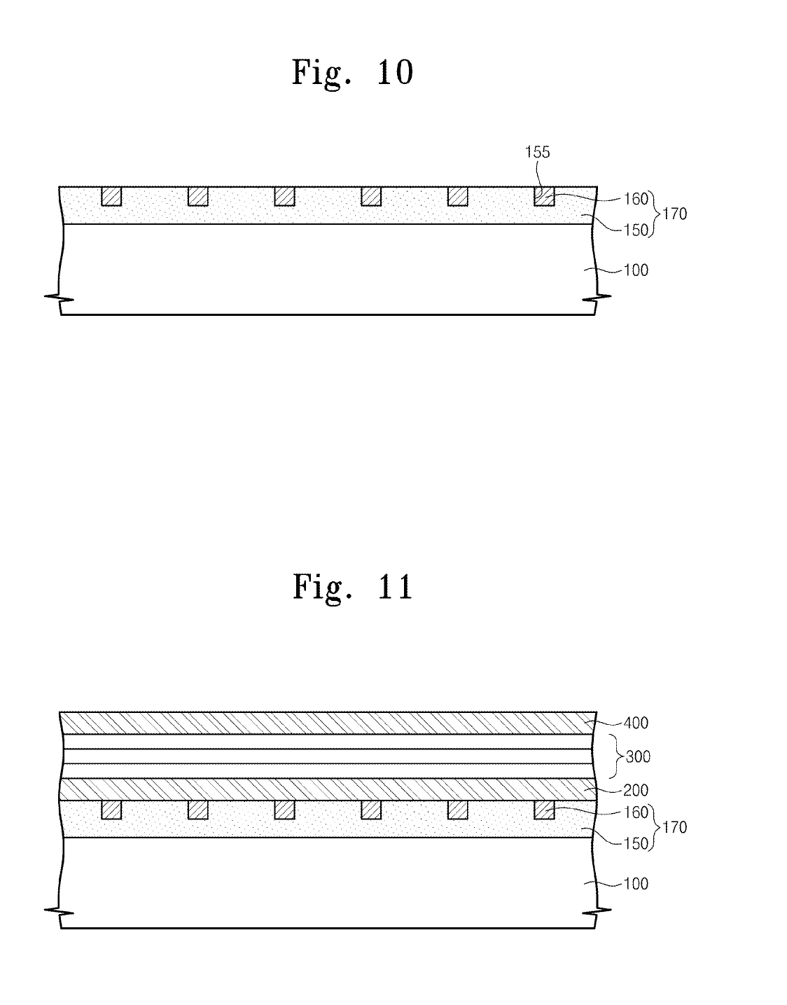

FIGS. 8, 10 and 11 are cross-sectional views illustrating a method of fabricating an organic light emitting diode according to other embodiments of the inventive concept, and FIG. 9 is a perspective view of a structure of FIG. 8. For the purpose of ease and convenience in explanation, the descriptions to the same elements as in the embodiment of FIGS. 3 to 7 will be omitted or mentioned briefly. That is, distinguishing features of the present embodiment will be mainly described hereinafter.

Referring to FIG. 8, an insulating layer 150 may be formed on a substrate 100. The insulating layer 150 may be formed on the substrate 100 by a spin coating method, a slot die coating method, or a slit die coating method. The insulating layer 150 may include at least one of polymethylmethacrylate (PMMA), polyimide (PI), polystyrene (PS), polyvinylphenol (PVP), acryl-based polymer, and epoxy-based polymer.

A trench 155 may be formed in the insulating layer 150. The insulating layer 150 may be pressured using an imprint roll, thereby forming the trench 155.

As illustrated in FIG. 9, the trench 155 may be formed in a mesh grid-shape in the insulating layer 150 in a plan view. The trench 155 may provide a space which will be filled with an assistant electrode formed in a subsequent process.

Referring to FIG. 10, a metal ink 160 may be formed to fill the trench 155. In some embodiments, after the metal ink 160 may be coated, a doctor blading method may be performed on the coated metal ink 160 to fill the trench 155. In other words, the doctor blading may be in contact with a top surface of the insulating layer 150 and then be moved, such that the metal ink 160 coated on the insulating layer 150 may fill the trench 155. The metal ink 160 in the trench 155 may correspond to an assistant electrode. A width of the metal ink 160 in the trench 155 may have a range of about 10 μm to about 200 μm.

Since the metal ink 160 fills the trench 155, an assistant electrode layer 170 including the insulating layer 150 and the metal ink 160 may be formed.

Referring to FIG. 11, a first electrode 200, an organic light emitting layer 300, and a second electrode 400 may be sequentially formed on the assistant electrode layer 170. The method of forming the first electrode 200, the organic light emitting layer 300, and the second electrode 400 may be substantially the same as the corresponding method in the embodiment described with reference to FIGS. 3 to 7. A protection layer (not shown) may further be disposed on the second electrode 400.

In the organic light emitting diode according to the present embodiment, since the assistant electrode layer 170 may be formed using a printing method or the doctor blading method, it is possible to simplify the fabricating method of the organic light emitting diode and to reduce fabricating cost. Additionally, since the assistant electrode layer 170 including the insulating layer 150 and the metal ink 160 embedded in the insulating layer 150 is formed between the substrate 100 and the first electrode 200, the formation of the conventional bank layer 251 of FIG. 1 may be omitted, and the height difference by the assistant electrode layer 170 may decrease to fabricate the high reliability organic light emitting diode.

In the organic light emitting diode according to embodiments of the inventive concept, the assistant electrode layer may be formed to include the insulating layer between the substrate and the anode and the assistant electrode embedded in the insulating layer. Thus, the bank layer separating the assistant electrode from the organic light emitting layer may be omitted. Additionally, the assistant electrode is embedded in the insulating layer, such that it is possible to prevent or minimize winding of the organic light emitting layer which may be caused by an assistant electrode. As a result, it is possible to simplify the fabricating method of the organic light emitting diode and to provide the high reliability organic light emitting diode.

In the method of fabricating the organic light emitting diode according to embodiments of the inventive concept, the assistant electrode layer including the insulating layer and the embedded assistant electrode may be formed by the printing method or the doctor blading method. As a result, an error rate of the processes may be reduced and the fabricating method may be simplified, such that the fabricating cost may be reduced.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A method of fabricating an organic light emitting diode, comprising:
forming an insulating layer on a substrate;
coating a metal ink on the insulating layer;
thermally treating the substrate to permeate the metal ink into the insulating layer, thereby forming an assistant electrode layer including the insulating layer and the metal ink embedded in the insulating layer; and
sequentially forming a first electrode, an organic light emitting layer, a second electrode on the assistant electrode layer.

2. The method of claim 1, wherein the insulating layer includes at least one of polymethylmethacrylate (PMMA), polyimide (PI), polystyrene (PS), polyvinylphenol (PVP), acryl-based polymer, and epoxy-based polymer.

3. The method of claim 1, wherein coating the metal ink comprises:
coating the metal ink in a mesh grid-shape on the insulating layer in a plan view.

4. The method of claim 1, wherein the metal ink includes at least one of silver (Ag), gold (Au), copper (Cu) and any alloy thereof.

5. The method of claim 1, wherein a width of the embedded metal ink has a range of about 10 μm to about 200 μm.

6. A method of fabricating an organic light emitting diode, comprising:
forming an insulating layer on a substrate;
forming a trench in the insulating layer;
filling the trench with a metal ink to form an assistant electrode layer including the insulating layer and the metal ink in the insulating layer; and
sequentially forming a first electrode, an organic light emitting layer, a second electrode on the assistant electrode layer.

7. The method of claim 6, wherein the insulating layer includes at least one of polymethylmethacrylate (PMMA), polyimide (PI), polystyrene (PS), polyvinylphenol (PVP), acryl-based polymer, and epoxy-based polymer.

8. The method of claim 6, wherein forming the trench comprises:
forming the trench in the insulating layer by using an imprint roll.

9. The method of claim 6, wherein forming the trench comprises:
forming the trench in the insulating layer in a mesh grid-shape in a plan view.

10. The method of claim 6, wherein forming the assistant electrode layer comprises:
filling the trench with the metal ink by a doctor blading method.

11. The method of claim 6, wherein the metal ink includes at least one of silver (Ag), gold (Au), copper (Cu) and any alloy thereof.

12. The method of claim 6, a width of the metal ink in the trench has a range of about 10 μm to about 200 μm.

13. An organic light emitting diode comprising:
a substrate;
a first electrode, an organic light emitting layer, and a second electrode sequentially stacked on the substrate; and
an assistant electrode layer disposed between the substrate and the first electrode,
wherein the assistant electrode layer includes an insulating layer and an assistant electrode embedded in the insulating layer.

14. The organic light emitting diode of claim 13, wherein the assistant electrode layer includes the assistant electrode formed in a mesh grid-shape in a plan view.

15. The organic light emitting diode of claim 13, wherein the insulating layer includes at least one of polymethylmethacrylate (PMMA), polyimide (PI), polystyrene (PS), polyvinylphenol (PVP), acryl-based polymer, and epoxy-based polymer.

16. The organic light emitting diode of claim 13, wherein the assistant electrode includes at least one of silver (Ag), gold (Au), copper (Cu) and any alloy thereof.

17. The organic light emitting diode of claim 13, wherein a width of the assistant electrode has a range of about 10 μm to about 200 μm.
